(19) United States
(12) Patent Application Publication
(10) Pub. No.: US 2024/0095895 A1
(43) Pub. Date: Mar. 21, 2024

(54) COMPONENT ANALYSIS FROM MULTIPLE MODALITIES IN AN INTERACTION ENVIRONMENT

(71) Applicant: Nvidia Corporation, Santa Clara, CA (US)

(72) Inventors: Ryan Albright, Beaverton, OR (US); Jordan Levy, Portland, OR (US); William Andrew Mecham, Elk Grove, CA (US); William Ryan Weese, Portland, OR (US); Benjamin Goska, Portland, OR (US); Aaron Richard Carkin, Hillsboro, OR (US); Michael Thompson, Wilsonville, OR (US)

(21) Appl. No.: 17/948,883

(22) Filed: Sep. 20, 2022

(51) Int. Cl. G06T 7/00; G06F 30/10; G06T 15/00

(52) U.S. Cl. CPC G06T 7/0002; G06F 30/10; G06T 15/005; G06T 2207/20212

(57) ABSTRACT

Systems and methods integrate different portions of a design review, such as files from a variety of different sources, into an interaction environment for review and interaction by a number of reviewing parties. The reviewing parties interact through an interface that is different from a native software of the files. An automated design review may be performed to evaluate a common rendering, formed from the files, for one or more conflicts, including interferences or version errors.

### BACKGROUND

Development and deployment of integrated systems, such as those including multiple mechanical, electrical, thermal, and other design requirements, may involve multiple levels of review from different contributors having varying skill levels. During development of these systems, various computational programs may be used to map out component locations, specify wiring or air flow paths, and build models of the systems prior to development of tooling and assembly procedures. However, different contributors have differing design goals in mind, and often, are not exposed to design considerations from others until late in the process. This may lead to interferences and sub-optimal designs. While periodic design reviews may catch these issues prior to final deployment, it may be challenging to have the necessary contributors review each level of a design due to gaps in knowledge, particularly when it comes to the advanced use of design software. As a result, development may be delayed until the appropriate parties can come together to do a review to enable each feature to be vetted and approved for distribution.

### BRIEF DESCRIPTION OF THE DRAWINGS

Various embodiments in accordance with the present disclosure will be described with reference to the drawings, in which:

FIG. 1 illustrates an example of an environment for rendering file within an interaction environment, according to at least one embodiment;

FIG. 2 illustrates example representation of individual files being rendered as a common assembly within an interaction environment, according to at least one embodiment;

FIG. 3 illustrates an example schematic diagram of a conflict system, according to at least one embodiment;

FIGS. 4A and 4B illustrate examples of an interface to identify conflicts within a common rendering, according to at least one embodiment;

FIG. 5A illustrates an example flow chart of a process for performing an automated assembly evaluation, according to at least one embodiment;

FIG. 5B illustrates an example flow chart of a process for performing an automated assembly evaluation, according to at least one embodiment;

FIG. 6 illustrates an example flow chart of a process for performing an automated assembly evaluation, according to at least one embodiment;

FIG. 7 illustrates an example data center system, according to at least one embodiment;

FIG. 8 illustrates a computer system, according to at least one embodiment;

FIG. 9 illustrates a computer system, according to at least one embodiment;

FIG. 10 illustrates at least portions of a graphics processor, according to one or more embodiments; and

FIG. 11 illustrates at least portions of a graphics processor, according to one or more embodiments.

### DETAILED DESCRIPTION

Approaches in accordance with various embodiments overcome these and other deficiencies by providing an interaction environment that can receive input files (e.g., images, video, text, database files, computer graphics files, computer-aided drafting (CAD) files, PCB gerbers, design logic, etc.) from a variety of different software modalities and integrate the files for interaction and viewing within a single interaction environment. The interaction environment may process the input file and then render the input files in a manner that would be done with the native program associated with the input file. For example, a three-dimensional (3D) computer-CAD file may be rendered as a 3D image that can be viewed from a variety of angles within the interaction environment. By combining viewing of multiple different files from different modalities into a single interaction environment, a user that is not well-versed in using Modality A could still provide an evaluation of one or more objects that were created by Modality A through use of the interaction environment. It should be appreciated that the interaction environment may not have the same characteristics as Modality A (e.g., may be read only, limited capability to execute program commands, etc.), but may provide one or more features suitable for review by one or more contributors.

In at least one embodiment, the system and interaction environment may be used for design reviews, where different part files for a common assembly may be loaded, rendered, and then checked for one or more conflicts. Conflicts may include mechanical interferences, electrical interferences, and the like. The conflicts may be defined by a set of rules, where different components may be identified and then evaluated against the set of rules to determine whether a conflict is present. For example, two components may be evaluated to ensure their boundaries do not overlap or that bolt holes are aligned. As another example, electrical connections may be checked to determine whether they are positioned within a threshold distance of a ground location. In this manner, different contributors with different levels of expertise may evaluate a common, unified assembly build with the assistance of one or more conflict checks, which may be automatically generated, for example, using one or more machine learning systems. Accordingly, the specified expert contributors may be notified of the conflict and then evaluate one or more specific locations, thereby streamlining their review while also highlighting potential problems with the design.

Embodiments of the present disclosure may also be used to harmonize or otherwise identify a design ground truth for different components forming an assembly. During a design process, there may be a number of different revisions and iterations. As a result, a final assembly build may include different conflicts due to revisions to one or more components not being carried through to other components. Various embodiments may evaluate a revision history for one or more components of a design to determine whether a previous version or build has fewer conflicts and/or errors when compared to a most-recent version or build. For example, metadata may be evaluated for different components to determine files associated with a revision history to determine which features may have changed over time. In this manner, it can be communicated to contributors whether one or more changes to revisions have caused more or fewer conflicts, and thereafter, contributors can determine whether the changes are worth the additional conflicts or may revert back to a previous design. Accordingly, systems and methods may be used with different stages of a design review.

It should be appreciated that while various embodiments may discuss a design review to join various 3D files into a common assembly, that systems and methods are not limited to these uses and may be implemented in a variety of different applications. For example, various embodiments may group or otherwise collect different portions of computer code, which may be written in different languages, to illustrate how a software package may be linked or grouped. In this example, a conflict may be directed toward an error in pulling data from one file type to another, among other options. Additionally, embodiments may render different 3D objects within the interaction environment to see how a gaming engine will render the objects and then compare features of those objects, such as scale or appearance to verify continuity. Accordingly, it should be appreciated that various embodiments may be used to receive and convert one or more files from different modalities for common interaction within an interaction environment.

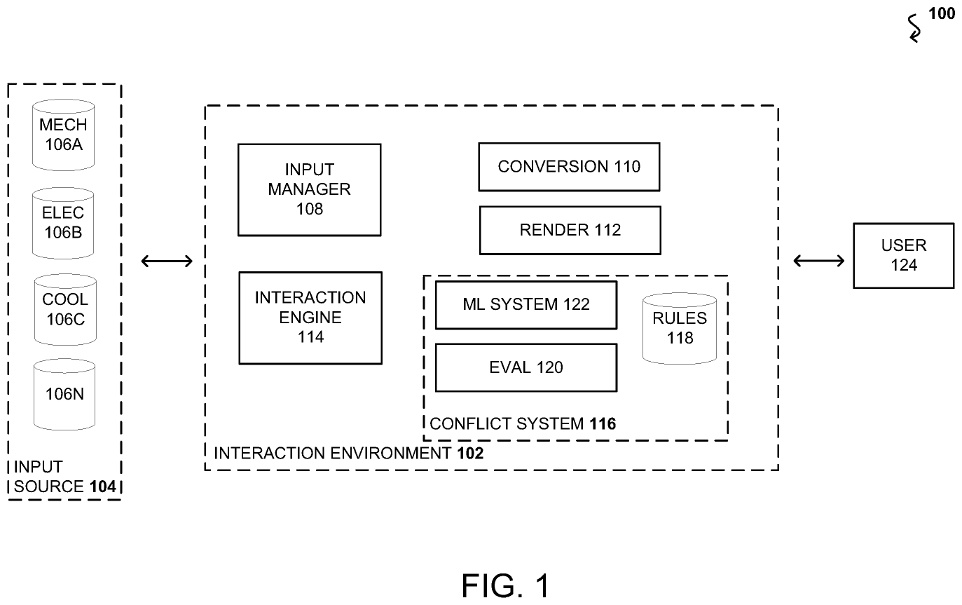

FIG. 1 illustrates an example environment 100 that can be used to provide such functionality in accordance with at least one embodiment. In this example, the environment may be associated with one or more interaction environments 102, which may include, or be in communication with, one or more software systems that enable execution of various functionality within the interaction environment 102. For example, different software systems may be associated with one or more memories or processors where stored instructions are executed by the one or more processors to perform one or more tasks. The interaction environment 102 may be executed using one or more remote compute resources, for example resources within a data center, that the user may provision in accordance with their needs.

In this example, an input source 104 includes a variety of different databases 106A-106N that may store and provide, to the interaction environment, one or more files for evaluation and presentation within the interaction environment 102. In this non-limiting example, the databases 106A-106N may include mechanical design files 106A, electrical design files 106B, cooling design files 106C (e.g., air flow or fluid mechanics), and any other number of reasonable design files 106N. It should be appreciated that more or fewer databases may be presented and, moreover, a common database may store design files generated with different modalities. The databases 106A-106N may be locally accessible by a processor associated with the interaction environment 102 or may be accessible via one or more network connections.

As noted above, various embodiments may include providing input files in the form of one or more CAD or design files, where the files may correspond to different components within a common assembly. For example, a first component may be for a frame of a server, a second component may be for a printed circuit board (PCB) for the sever, a third component may be a wiring diagram for the server, and the like. These files may be generated by one or more different users or contributors using different modalities (e.g., different software packages) and may be provided to the interaction environment 102 at an input manager 108. The input manger 108 may evaluate the files provided from the input source 104 to determine whether the files have the requisite compatibility with the interaction environment 102, whether users of the interaction environment 102 have the appropriate permissions to add or view of the files, and the like. For example, certain confidential designs may have restricted access, and as a result, users permitted to view those files and/or add the files may need to have certain permissions or provide credentials to permit addition to the interaction environment 102. Additionally, in at least one embodiment, the input manager 108 may also evaluate information associated with the files, such as metadata, related files, revision history, and the like.

A conversion engine 110 may convert one or more features of the files for use within the interaction environment 102. For example, the conversion engine 110 may convert a format of the files for use with the interaction environment 102. Additionally, the conversion engine 110 may change one or more features, such as a font of text or a color of an item, to conform to one or more settings or permissions within the interaction environment 102. A rendering engine 112 may render the files, for example, when the files include one or more image or video files. By way of example, for a design review, the files may include one or more CAD files, and different components may be rendered within a 3D environment to permit viewing of the components from a variety of different perspectives. In at least one embodiment, the rendering engine 112 may combine or otherwise associate components with one another such that multiple files appear as a single assembly. For example, a bill of materials or a build list may be accessed and the interaction environment 102 may assemble different components together based on instructions from the build list. This rendering may be done based, at least in part, on one or more rules or parameters associated with an interaction engine 114. The interaction engine 114 may be used to display and provide one or more controls to a user interacting with the interaction environment 102. For example, controls may include visual controls that allow the user to zoom in/out, pan, rotate the assembly, and the like. Controls may also include removal of certain components or highlighting certain components. Additionally, further visual controls may be provided with respect to an appearance of the assembly and/or components, such as a view direction, colors, shading, opaqueness, and the like. Moreover, exploded views, side views, top views, and the like may also be options to permit the user to view the assembly and/or components of the assembly from a variety of different angles and perspectives. It should be appreciated that the interaction engine 114 may also permit the user to add notes or comments to different components, such as adding a note at a certain location to indicate an undesirable interference or the like.

Various embodiments may include a conflict system 116 that may be used to automatically identify conflicts within the assembly based, at least in part, on one or more rules 118. For example, the rules 118 may specify distances between physical or solid components, distances between an electrical connection and a ground, distances between an electrical connection and a metallic component, thicknesses for insulation, cross-sectional areas for air flow, and the like. The rules may be project specific or may be from a global set of rules, for example from a set of design considerations specified by one or more manufacturers. Additionally, in at least one embodiment, the one or more rules may not be binary (e.g., conflict/no conflict) but may include a range or a spectrum. For example, conflicts may be graded or otherwise categorized by severity, such as by using a number system (e.g., 1-10), a color system (e.g., green, yellow, red), or the like. As a result, a reviewing user may identify areas that could potentially cause a conflict and then determine whether to perform one or more action to correct the potential conflict or to reduce a severity of the conflict.

An evaluation module 120 may perform different comparisons and evaluations of the components forming the assembly using the one or more rules 118. For example, the evaluation module 120 may select a component, identify a component type (e.g., structural, electrical, etc.), and then evaluate one or more rules based on that component type. In at least one embodiment, metadata may be used to provide information for the evaluation module 120 to make various identifications. Furthermore, in certain embodiments, a machine learning system 122 may include features such as object detection in order to identify different components within an assembly. For example, a PCB shape may be recognized, such as by its outline, and thereafter one or more rules may be selected in accordance with the recognized PCB shape.

In operation, a user 124 may access the interaction environment 102, for example by providing credentials or the like, and then interact with an assembly by selecting different component files to serve as the input. The user 124 could conduct a design reviewer, evaluate identified conflicts, and then comments or approvals for different phases of the design. As noted above, the user 124 may not be well versed in each modality used to generate the files from the input source 104, but due to the interaction engine 114, may be well-versed in the interaction environment 102 to permit analysis and evaluation. Additionally, the user 124 may provide comments or other suggestions for other contributors to evaluate various aspects of the design.

Embodiments of the present disclosure may overcome problems associated with obtaining review of different phases of a design process by the necessary contributors (e.g., experts, interested parties, users, etc.) when certain portions of the design are generated and managed by software systems that the contributors may not be familiar with. Additionally, systems and methods provide for harmonization and alignment between different design systems such that the review can be substantially software system agnostic. By combining components generated with different modalities into a single reviewable location, overall design assemblies can be reviewed by multiple contributors in order to identify and remediate conflicts. In at least one embodiment, an initial evaluation may be performed by the system to quickly identify conflicts based on one or more rules. Furthermore, human reviewers can also evaluate different aspects of the assembly to identify additional conflicts and/or to provide feedback on conflicts identified by the automatic review. Accordingly, systems and methods provide for advanced review of design systems within a common interaction environment that can aggregate and compile information from different modalities.

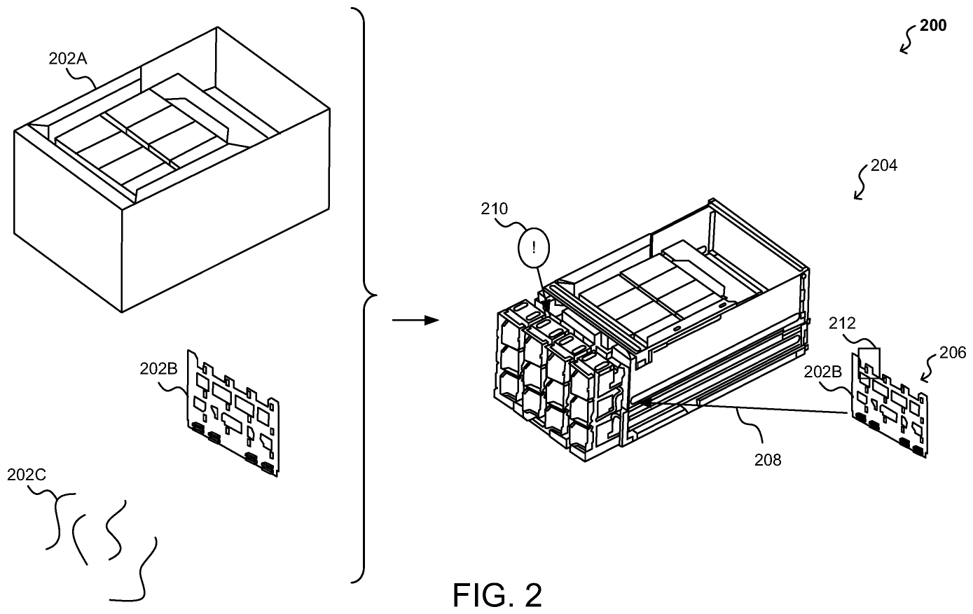

FIG. 2 illustrates an example environment 200 that can be used to collect different files, such as part files, from different software modalities to render the different files as an assembly within an interaction environment. In this example, different part files 202A-202C are being used within the interaction environment 102. As noted, the part files 202A-202C may be extracted from one or more input sources 104, and may be associated with different parent software modalities, which may each have different native file formats. For example, the first part file 202A may be a mechanical CAD file showing a structural frame. The second part file 202B may be a PCB board that is designed using a different software engine. The third part file 202C may be an electrical wiring configuration, which may also be designed using another different software engine. As a result, the three part files 202A-202C may each be associated with different modalities where one or more contributors to the project may not have sufficient skill to provide review and analysis of related parts. For example, a mechanical designer may be well versed on CAD, but may not understand how to use software for wiring diagrams. However, it is important for the functionality of the product for the wiring diagrams to fit within the different mechanical parts to avoid pinch points, to align with different openings, and the like.

Embodiments of the present disclosure may generate an assembly 204 that combines information from each of the part files 202A-202C, among other part files, to generate a 3D rendering. This 3D rendering of the assembly 204 illustrates each of the components associated with their respective part files 202A-202C as they would be assembled for use, for example within a datacenter. As shown, the PCB is mounted to the structural frame and the wiring of the wiring diagram may extend to and through various components of the assembly 204. By only looking at the parts individually, interferences or conflicts may not be readily addressed. For example, an aperture for fastening the PCB to the structural frame may not be aligned with a mating aperture on the structural frame. While these parts may have, at one time, been aligned, different design changes and revisions may have caused certain components to diverge or otherwise be modified. Embodiments of the present disclosure may be used to review and identify such inconsistencies between component parts in a common viewing environment, which may permit holistic design reviewers, as opposed to piecemeal evaluation on a part-by-part basis.

In this example, the second part file 202B associated with the PCB has been selected and is shown separately as an exploded component 206. For example, during the review, a contributor may wish to take a closer look at the second part file 202B and may select, either by clicking on the part itself or by selecting the part from an interactive list, among other options, such that the part is identified within the assembly 204 and then provided for further review. The interactive list may be provided, at least in part, by a build list or a bill of materials associated with the individual part files, where parts may be labeled and presented by name for simplified review. In this example, an indicator 208 shows where the component associated with the second part file 202B is located within the assembly 204 as a whole. The contributor may now review different information associated with the second part file 202B. For example, different shapes and openings may be identified, a version number may be evaluated, and other information. In at least one embodiment, additional information may be provided as a new pop up window or as an overlay.

As noted, various embodiments may provide for conflict evaluation between different components forming the assembly 204. For example, interference checks may be conducted to determine whether different solid parts are overlapping or otherwise blocking one another. Additionally, alignment checks may be performed to ensure different apertures are aligned to permit fasteners and the like to pass through. Furthermore, grounding checks may be performed to determine whether hot electrical components are ungrounded within the assembly. Various other checks may also be performed in accordance with one or more rules provided to the interaction environment 102.

In at least one embodiment, identified conflicts may be flagged or otherwise brought to the attention of one or more reviewers, such as a human reviewer. For example, a misaligned aperture may be noted and then identified with a message or icon 210. As shown in FIG. 2, an interference is identified by the icon 210 and is associated with the component of the second part file 202B. This icon 210 may have caused the reviewer to select the component of the second part file 202B. In the exploded view 206, an area of interest 212 is highlighted, associated with the message or icon 210. Accordingly, the reviewer may select the area of interest 212 to obtain more information, such as the type of conflict, possible causes of the conflict, whether the conflict has persisted through different versions of the components, and the like.

Embodiments of the present disclosure may provide an interaction environment for one or more users to evaluate a combined rendering of a variety of different part files, where the part files may be generated using different software modalities (e.g., different from one another and different from the interaction environment). The users may select files to load into the interaction environment to build out the rendering, which in certain instances, may include generating an assembly illustrating how different components will be joined together. One or more rules may be used in order to identify defined conflicts between the components, such as interferences are electrical problems. These problems may be flagged or otherwise identified so that the user may take a closer look and provide feedback, override the conflict, or the like. Furthermore, various embodiments permit contributors to review the assembly without the use of the automated review. Additionally, systems and methods may be used to verify different versions of part files by checking metadata or other information for different components to determine whether different versions cause more or fewer conflicts, thereby providing further guidance during the design reviews.

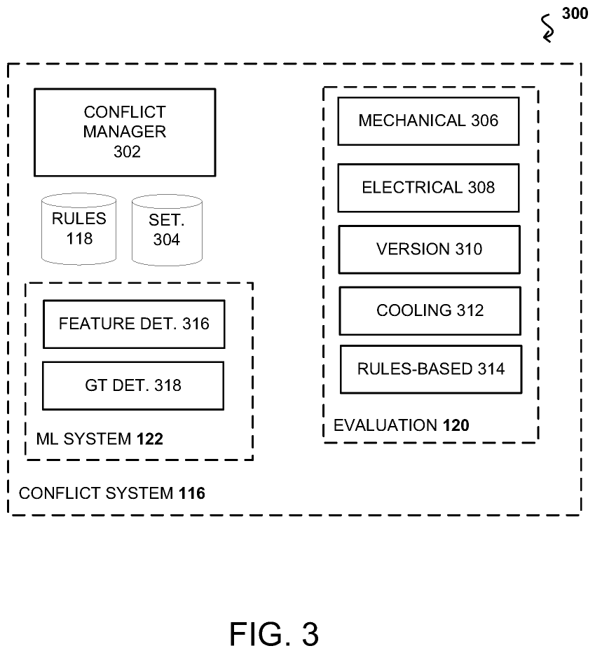

FIG. 3 illustrates a schematic diagram of an example environment 300 that may be used with respect to the conflict system 116. The example environment 300 may execute on one or more processors based on instructions stored on one or more memories. Different portions of the environment may also be stored remotely or locally for access via one or more networks. In at least one embodiment, one or more features are part of a service provided through a distributed computing environment. In this example, the conflict system 116 includes a number of different software features, but it should be appreciated that there may more be or fewer than those shown in FIG. 3 and that FIG. 3 is being provided by way of illustrative example.

A conflict manager 302 may be used to control or otherwise route requests to evaluate different potential conflicts when one or more different source files are provided to the interaction environment 102. The conflict manager 302 may, for example, determine different file types, determine potential conflicts associated with those file types, track different conflicts that are identified, rank the conflicts, and the like. In at least one embodiment, the conflict manager 302 may be used to output or otherwise provide information to a user of the interaction environment. For example, the conflict manager 302 may be used to prepare messages that may be provided to the user or to determine locations to provide indicators regarding conflicts.

The illustrated embodiment includes the rules database 118 along with a setting database 304. The rules database 118 may be populated by an organization and may include different design or evaluation principles to be checked. For example, organizations may have preferences when it comes to how certain items are arranged within an assembly. Additionally, industry codes or best practices may be provided and used within the rules database. The settings database 304 may determine a user of the interaction environment and particularly select certain conflicts for the user to evaluate. For example, if a design review for a server product was being performed, an electrical expert may not be interested in conflicts regarding different components aligning within the case. However, the electrical expert may be interested in conflicts regarding how wires are routed through the structure. Accordingly, a user may be determined and then particular information relevant to the user may be presented, which may help streamline or otherwise simplify the review process.

The evaluation module 120 is used to evaluate one or more conflicts that may arise when different file types from different modalities are rendered within the interaction environment. In this example, the conflicts are related to a design review for how to build a particular assembly, but it should be appreciated that this is by way of example only and not intended to limit the scope of the present disclosure. Accordingly, while particular design reviews may include evaluations of mechanical interference and the like, it should be appreciated that other reviews for different end products may have different conflict checks. For example, for a graphical rendering, sizes of different objects within the rendering may be checked to ensure scale is proper. As another example, for a code review, different syntax may be checked for conflicts.

In this example, different evaluations may include mechanical interference 306, electrical interference 308, version control 310, cooling analysis 312, and rules-based analysis 314, which may include one or more additional evaluations selected by the organization or a particular user. Mechanical interference 306 may look for overlaps between borders or boundaries of solid objects, which may be determined from different information extracted from part files. Such an evaluation may include a volumetric difference check. Electrical interference 308 may evaluate whether live wires contact metallic components, whether different components are grounded, whether different components are receiving power, and the like. Version control 310 may check which version of different part files are being used and may, in certain embodiments, default to using a latest version, which may be based on checking metadata for a created or last-saved date. Cooling analysis 312 may check air or water cooling against one or more desired parameters. For example, the cooling analysis 312 may leverage cooling analysis performed by a different program and then overlay that analysis on the rendering to ensure that expected flow paths are present in the rendered build. The rules-based analysis 314 may include one or more additional or alternative rules, which may be set by the organization using the interaction environment. In this manner, organizations and users may tune their conflicts analysis for particular projects.

In at least one embodiment, a machine learning system 122 may be used to facilitate identification of component parts and/or recognize different conflicts. For example, a trained machine learning system may include one or more computer vision systems that evaluate a component, identify one or more particular features within the component, and then determine a relative position of the feature, within a 3D space, with respect to different features. In this manner, different evaluations such as overlapping boundaries, threshold distances between features, and the like may be determined. A feature detection system 316 is one such example of a trained computer vision system that may be used to recognize different features within components or the assembly as a whole. In one example, the feature detection system 316 may evaluate outlines or perimeters of components, such as the PCB in FIG. 2. In another example, the feature detection system 316 may scan or evaluate the entire assembly for identification of specific features, such as fasteners, solder connections, or the like. In this manner, particular features may be identified and then one or more rules may be checked to determine whether and what type of evaluation corresponds to those features.

Various embodiments may also provide for a ground truth detection system 318. As noted above, with examples such as design reviews, different components may go through various rounds of revisions or versioning. Often, teams may be working on their particular areas and may not communicate changes to others. This may lead to assemblies that are generated using older versions, which may not only have conflicts with the existing designs, but may not accurately reflect a final design that may have more conflicts. In at least one embodiment, the ground truth detection system 318, which may receive information from the version control 310, is used to evaluate and determine a latest version of each of the files added to the interaction environment and also to provide an analysis of older versions in the event of one or more conflicts or errors. For example, one or more repeated errors may be representative of a miscommunication between teams, such as sets of fastener apertures being misaligned. The ground truth detection system 318 may include a set of rules and an ordering in which parts are checked. As one example, a preliminary evaluation may be based on a latest version of each file, which may be based on an assigned version number, information within the file title, created on or last updated dates, or the like. Alternatively, or in addition, the system 318 may ask the user if the latest versions are being used for confirmation prior to rendering, thereby conserving resources. In at least one embodiment, multiple renderings and conflict checks may be performed using different versions to determine whether reverting back to a previous build would cause fewer conflicts.

Systems and methods provide for the conflict system 116 to evaluate one or more features of a multi-modality assembly generated using different component files. The conflict system 116 may check for a variety of user or system defined conflicts to identify areas for improvement. In at least one embodiment, the initial conflict check is performed automatically, thereby saving review time for users who may load the assembly and then receive a prompt that identifies one or more conflicts or areas of attention for the user. The user may then spend a majority of their time evaluating these specific identified areas, rather than checking areas that have passed conflict checks. Furthermore, in at least one embodiment, users may receive information regarding conflicts that arise in files generated by modalities they may not be familiar with, which provides opportunities for additional contribution to the overall design.

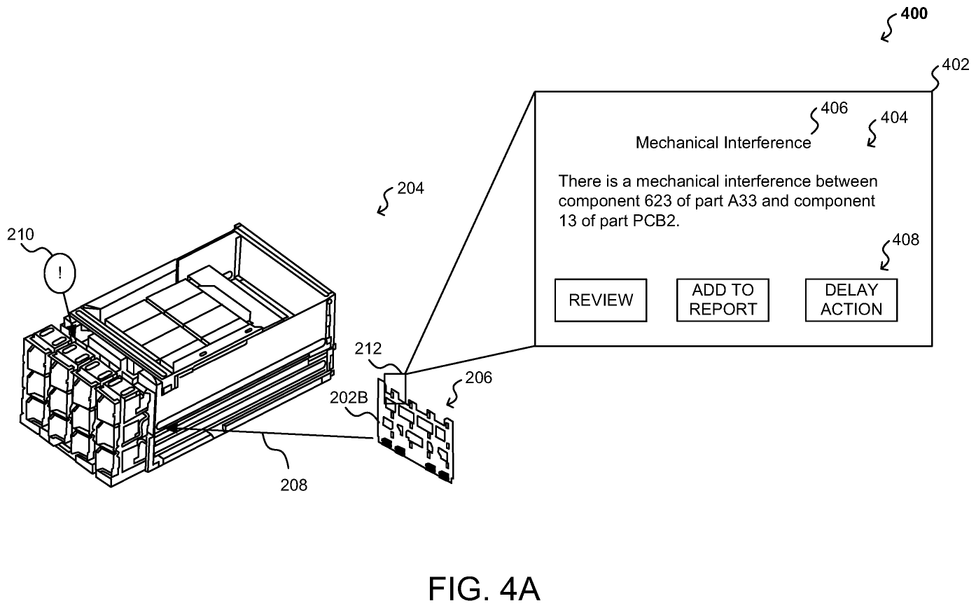

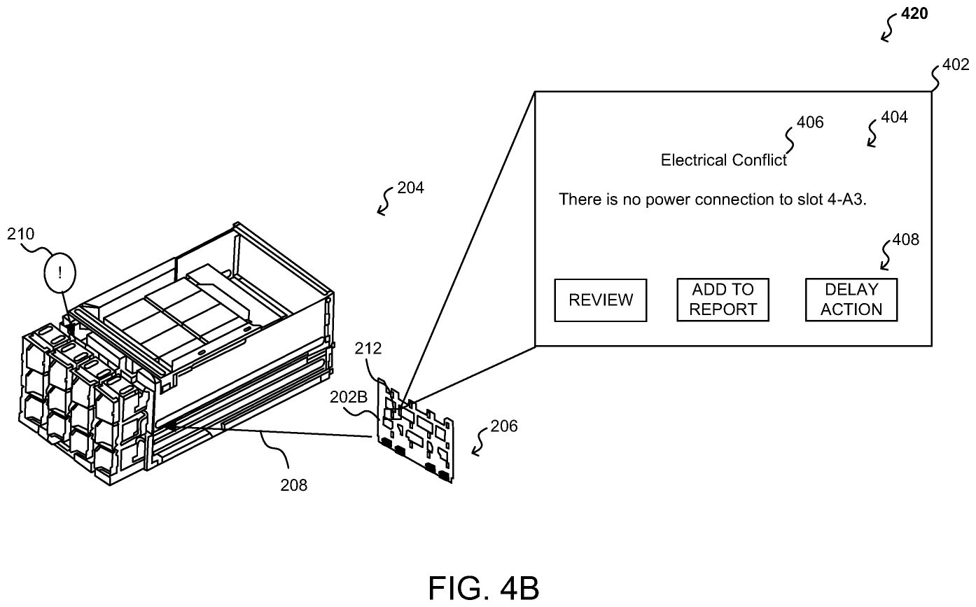

FIG. 4A illustrates an example interface 400 that can be provided with the interaction environment 102 responsive to identification of one or more conflicts. In this example, the assembly 204 is shown to include at least one conflict, as identified by the icon 210. As previously indicated, the icon 210 may provide an indication that some attention is required from the user, where the user can then select the icon 210. Selection of the icon 210 may isolate one or more components, such as the exploded view 206 provided of the PCB corresponding to the file 202B. The area of interest 212 may be highlighted. Particular highlights may be enabled using the machine learning systems that may perform feature detection in order to identify specific features where conflicts arise.

In at least one embodiment, a user may select the area of interest 212 and be provided with a notification 402, which is shown in the form of a pop-up message or overlay, providing information indicative of the conflict or why the icon 210 was arranged at the location. As shown, the notification 402 includes a textual message 404 that provides a conflict type 406, an identification of a conflict location, identification of conflicting components, and also a series of interactable items 408 that the user may select to perform one or more follow on actions responsive to the notification 402.

Providing the conflict type 406 may enable a user to quickly determine whether the conflict type is one which they can provide assistance. For example, an expert in electric design may not be concerned with interference between coupling sections of the frame. Similarly, an expert in mechanical design may not wish to modify a wire routing configuration when another contributor may provide an improved solution to a potential conflict. In this example, the interactable items 408 enable the user to perform different follow on actions. As an example, the user may select a deeper review of the issues, which may include closer views of the components causing the conflict, additional location information, and the like. Adding the item to the report may be used to compile a list of conflicts for later review and evaluation. Delaying an action may be selected if the user is not an expert or not assigned to address such a conflict. Based on the user selection, the conflict may then be deemed as being addressed by the user or may remain during later viewings, which may depend on the user preferences.

FIG. 4B illustrates an example interface 420 that can be provided with the interaction environment 102 responsive to identification of one or more conflicts. In this example, the assembly 204 is shown to include at least one conflict, as identified by the icon 210. As previously indicated, the icon 210 may provide an indication that some attention is required from the user, where the user can then select the icon 210. Selection of the icon 210 may isolate one or more components, such as the exploded view 206 provided of the PCB corresponding to the file 202B. The area of interest 212 may be highlighted. Particular highlights may be enabled using the machine learning systems that may perform feature detection in order to identify specific features where conflicts arise.

In at least one embodiment, a user may select the area of interest 212 and be provided with the notification 402, which is shown in the form of a pop-up message or overlay, providing information indicative of the conflict or why the icon 210 was arranged at the location. As shown, the notification 402 includes the textual message 404 that provides the conflict type 406, identification of a conflict location, identification of conflicting components, and also a series of interactable items 408 that the user may select to perform one or more follow on actions responsive to the notification 402.

As noted, providing the conflict type 406 may direct or otherwise alert a particular reviewer that the conflict is within the realm of their review. For example, for the notification 402 in FIG. 4B, a reviewer concerned with the electrical connections may wish to address the identified electrical conflict. However, it should be appreciated that the conflict may arise from alternative issues. For example, the electrical connection may have been severed due to changes in a position of a wire, which may lead to additional levels of conflicts and conflict reviews to complete the design review.

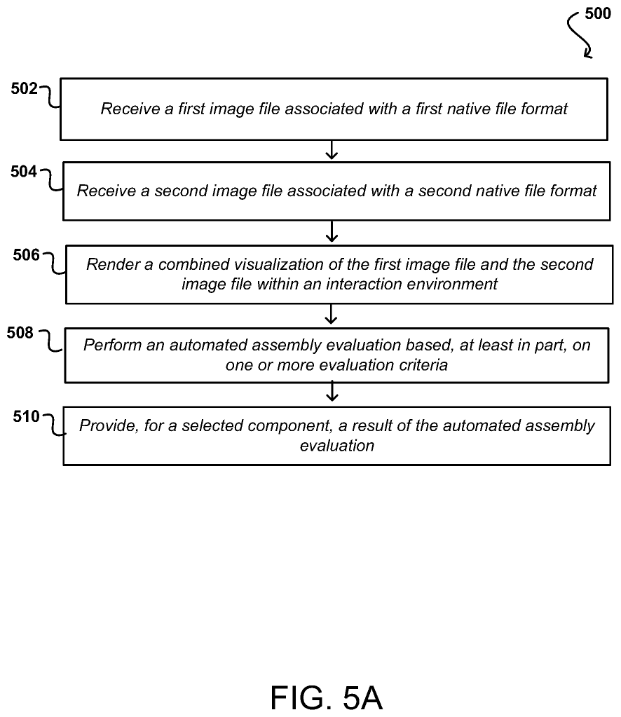

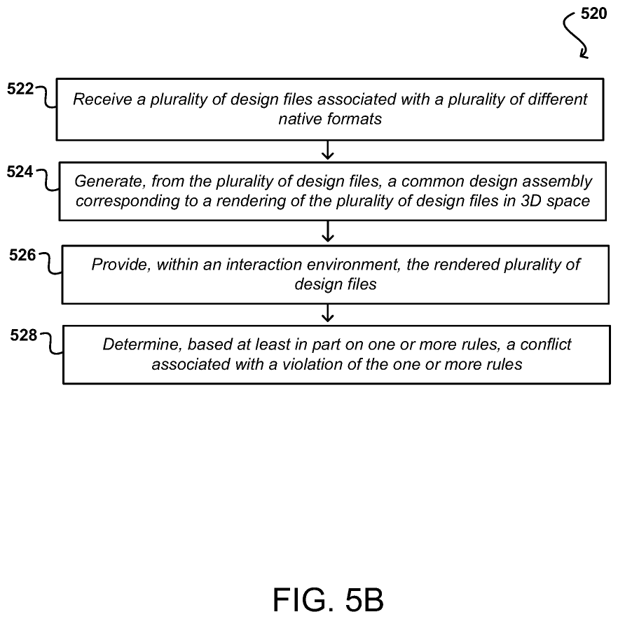

FIG. 5A illustrates an example process 500 for evaluating components forming an assembly during a design review. It should be understood that for this and other processes presented herein that there can be additional, fewer, or alternative steps performed in similar or alternative order, or at least partially in parallel, within the scope of various embodiments unless otherwise specifically stated. In this example, a first image file is received 502. The first image file may be associated with a first native file format, which may correspond to one or more software programs used to create, at least in part, one or more objects represented by the first image file. A second image file may also be received 504, where the second image file is associated with a second native file format. In various embodiments, the first and second native file formats are not compatible with one another. That is, a software package used to open and execute the first native file format would not be able to open the second native file format, and vice versa.

A combined visualization may be rendered 506 using the first and second image files. In at least one embodiment, the rendering is a 3D rendering that is viewable within an interaction environment. The rendering may separately illustrate the first and second image files or may combine the first and second image files into a common rendering, for example, illustrating various interactions between objects represented by the first and second image files. In at least one embodiment, the objects are 3D designs for components that are joined together in an assembly within the interaction environment. The interaction environment may include one or more software systems that enable differences between the first and second native file formats to be addressed such that the underlaying objects may be separately rendered and displayed for the viewer. For example, the interaction environment may identify one or more components of the objects, such as an outline or a specific feature, and may use that information to render the object, even if other capabilities of the native file format are not available. Continuing with the example of a 3D design file, the native file format may be used for computational flow dynamics and may include an outline of an object that is used for various calculations. When added to the interaction environment, an associated file may be evaluated to extract points of the object so that the object can be rendered. In at least one embodiment, further actions may not be performed within the environment, such as the calculations associated with flow, which may need to be performed within the native program.

An automated assembly evaluation may be performed 508, where one or more evaluation criteria are used to identify one or more conflicts within the assembly. Conflicts may include a variety of errors or potential constraints, such as mechanical interference, electrical connections, grounding errors, and the like. The evaluation criteria may be associated with one or more rules that are checked against features of the assembly. For example, interference rules may identify regions where object boundaries cross. As another example, electrical connection rules may identify locations where live electrical wires are within a threshold distance of a metallic component. In at least one embodiment, the rules of the evaluation criteria may be provided by an associated user.

Results of the automated assembly evaluation may be provided for a selected component 510. For example, one or more conflicts may be identified and a user may select a component corresponding to the conflict to receive additional information about the conflict. Conflicts may provide notices for users performing a design review to determine whether an assembly, which may include any number of component parts, is arranged in a way that would allow construction and operation of the assembly. In at least one embodiment, a report may be generated to provide results for each component within the assembly or to provide a general evaluation of the assembly for further review.

FIG. 5B illustrates an example process 520 for evaluating components forming an assembly during a design review. In this example, a plurality of design files associated with a plurality of different native formats are received 522. For example, a first design file may be associated with a mechanical CAD program, a second design file may be associated with an electrical CAD program, a third design file may be associated with an electrical wiring and trace program, and a fourth design file may be associated with an air flow design program. These different design files may use different underlaying software for evaluation and updates. For example, the electrical CAD program may not be able to open, review, and update the mechanical CAD program. An interaction environment that receives these files may generate, from the plurality of design files, a common design assembly for presentation within the interaction environment 524. In at least one embodiment, the common design assembly may include a rendering in 3D space of an appearance of the design assembly. It should also be appreciated that instead of generating an assembly, the interaction environment may permit viewing of individual components.

The interaction environment may provide, to a user, the rendering of the design assembly 526. Within the interaction environment, the user may be able to view or otherwise manipulate the design assembly, such as by selecting particular components, changing a view, and the like. The interaction environment may be configured for conflict evaluation, where the design assembly is checked against one or more rules associated with a design review. A conflict may be determined from evaluation of these one or more rules against the design assembly 528. For example, one or more rules may be used to find misalignment between fastener apertures or to identify electrical components that are not coupled to a power source, among other options. These conflicts may then be provided to one or more users for further review and evaluation, which may lead to updating the native files and then generating a second design assembly rendering after the changes are implemented.

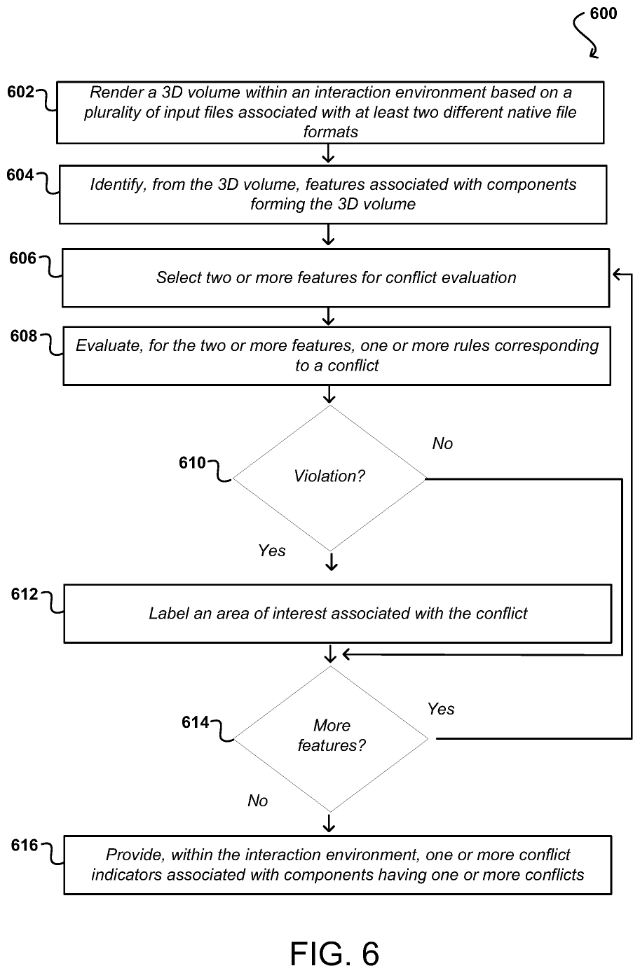

FIG. 6 illustrates an example process 600 for performing a conflict analysis on a rendered component. In this example, a 3D volume is rendered using a plurality of input files associated with at least two different native file formats 602. For example, a portion of the input files may be mechanical CAD files associated with a first CAD program and a portion of the input files may be electrical CAD files associated with a second CAD program. The rendered 3D volume may be provided within an interaction environment, which may include separate controls from either the first or second CAD programs to permit a user to view and/or interact with the rendered 3D volume.

In at least one embodiment, one or more features are identified within the 3D volume 604, with the features corresponding to different parts of components forming the 3D volume. For example, a feature may include an aperture for a fastener, an electrical wire, or the like. Two or more features may be selected for conflict evaluation 606. Selection of components and/or features of the components, may be based, at least in part, on a proximity of the features or components to one another. In at least one embodiment, one or more rules may be established for feature or component selection. For example, components that are coupled together may be evaluated but components that do not touch or are spaced apart greater than a threshold may not be selected for evaluation. The selected two or more features may be evaluated for conflicts based, at least in part, on one or more rules 608. The one or more rules may be design criteria or best practices set by an operator, among other options.

It may be determined whether one or more rule are violated 610. Violation of one or more rule may be determined to be a conflict or interference, which may lead to an error when manufacturing or using the 3D volume. If there is a violation, an area of interest may be labeled for further evaluation 612. Thereafter, it may be determined whether the 3D volume includes additional features for evaluation 614. If not, one or more conflict indicators may be provided within the interaction environment 616. The conflict indicators may then be used to provide notifications to one or more users reviewing the 3D volume regarding areas that may require further evaluation and consideration.

### Data Center

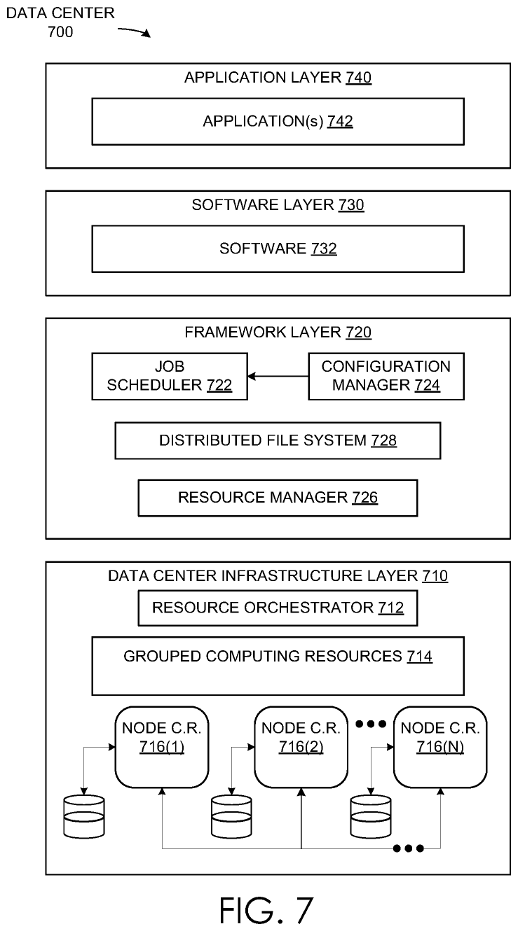

FIG. 7 illustrates an example data center 700, in which at least one embodiment may be used. In at least one embodiment, data center 700 includes a data center infrastructure layer 710, a framework layer 720, a software layer 730, and an application layer 740.

In at least one embodiment, as shown in FIG. 7, data center infrastructure layer 710 may include a resource orchestrator 712, grouped computing resources 714, and node computing resources (“node C.R.s”) 716(1)-716(N), where “N” represents any whole, positive integer. In at least one embodiment, node C.R.s 716(1)-716(N) may include, but are not limited to, any number of central processing units (“CPUs”) or other processors (including accelerators, field programmable gate arrays (FPGAs), graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 716(1)-716(N) may be a server having one or more of above-mentioned computing resources.

In at least one embodiment, grouped computing resources 714 may include separate groupings of node C.R.s housed within one or more racks (not shown), or many racks housed in data centers at various geographical locations (also not shown). Separate groupings of node C.R.s within grouped computing resources 714 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 712 may configure or otherwise control one or more node C.R.s 716(1)-716(N) and/or grouped computing resources 714. In at least one embodiment, resource orchestrator 712 may include a software design infrastructure (“SDI”) management entity for data center 700. In at least one embodiment, resource orchestrator may include hardware, software or some combination thereof.

In at least one embodiment, as shown in FIG. 7, framework layer 720 includes a job scheduler 722, a configuration manager 724, a resource manager 726 and a distributed file system 728. In at least one embodiment, framework layer 720 may include a framework to support software 732 of software layer 730 and/or one or more application(s) 742 of application layer 740. In at least one embodiment, software 732 or application(s) 742 may respectively include web-based service software or applications, such as those provided by Amazon Web Services, Google Cloud and Microsoft Azure. In at least one embodiment, framework layer 720 may be, but is not limited to, a type of free and open-source software web application framework such as Apache Spark™ (hereinafter “Spark”) that may utilize distributed file system 728 for large-scale data processing (e.g., “big data”). In at least one embodiment, job scheduler 722 may include a Spark driver to facilitate scheduling of workloads supported by various layers of data center 700. In at least one embodiment, configuration manager 724 may be capable of configuring different layers such as software layer 730 and framework layer 720 including Spark and distributed file system 728 for supporting large-scale data processing. In at least one embodiment, resource manager 726 may be capable of managing clustered or grouped computing resources mapped to or allocated for support of distributed file system 728 and job scheduler 722. In at least one embodiment, clustered or grouped computing resources may include grouped computing resource 714 at data center infrastructure layer 710. In at least one embodiment, resource manager 726 may coordinate with resource orchestrator 712 to manage these mapped or allocated computing resources.

In at least one embodiment, software 732 included in software layer 730 may include software used by at least portions of node C.R.s 716(1)-716(N), grouped computing resources 714, and/or distributed file system 728 of framework layer 720. The one or more types of software may include, but are not limited to, Internet web page search software, e-mail virus scan software, database software, and streaming video content software.

In at least one embodiment, application(s) 742 included in application layer 740 may include one or more types of applications used by at least portions of node C.R.s 716(1)-716(N), grouped computing resources 714, and/or distributed file system 728 of framework layer 720. One or more types of applications may include, but are not limited to, any number of a genomics application, a cognitive compute, and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 724, resource manager 726, and resource orchestrator 712 may implement any number and type of self-modifying actions based on any amount and type of data acquired in any technically feasible fashion. In at least one embodiment, self-modifying actions may relieve a data center operator of data center 700 from making possibly bad configuration decisions and possibly avoiding underutilized and/or poor performing portions of a data center.

In at least one embodiment, data center 700 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 700. In at least one embodiment, trained machine learning models corresponding to one or more neural networks may be used to infer or predict information using resources described above with respect to data center 700 by using weight parameters calculated through one or more training techniques described herein.

In at least one embodiment, data center may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Such components can be used for interaction environments.

### Computer Systems

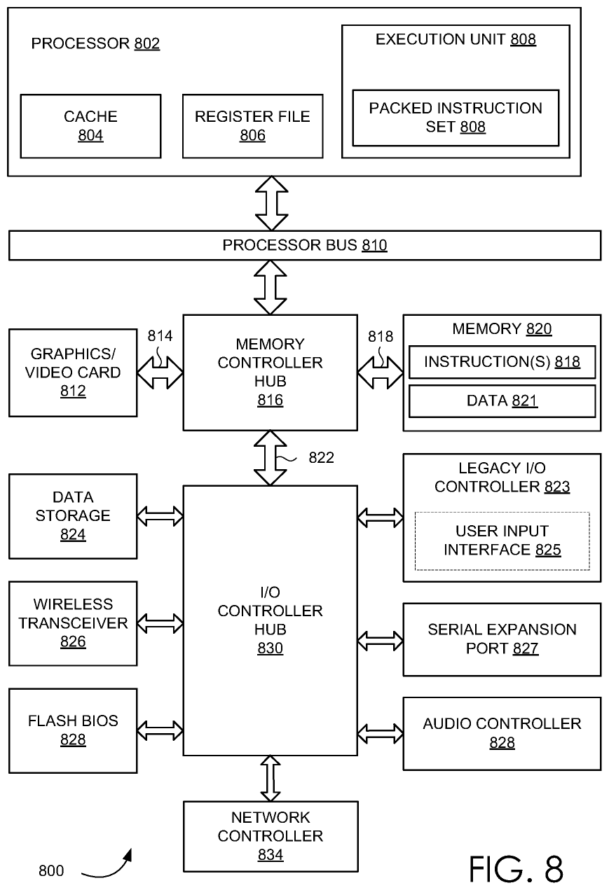

FIG. 8 is a block diagram illustrating an exemplary computer system, which may be a system with interconnected devices and components, a system-on-a-chip (SOC) or some combination thereof 800 formed with a processor that may include execution units to execute an instruction, according to at least one embodiment. In at least one embodiment, computer system 800 may include, without limitation, a component, such as a processor 802 to employ execution units including logic to perform algorithms for process data, in accordance with present disclosure, such as in embodiment described herein. In at least one embodiment, computer system 800 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 800 may execute a version of WINDOWS' operating system available from Microsoft Corporation of Redmond, Wash., although other operating systems (UNIX and Linux for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), system on a chip, network computers (“NetPCs”), edge computing devices, set-top boxes, network hubs, wide area network (“WAN”) switches, or any other system that may perform one or more instructions in accordance with at least one embodiment.

Embodiments of the systems and methods described herein may be used for a variety of purposes, by way of example and without limitation, for machine control, machine locomotion, machine driving, synthetic data generation, digital twinning, model training, perception, augmented reality, virtual reality, mixed reality, robotics, security and surveillance, autonomous or semi-autonomous machine applications, deep learning, environment simulation, data center processing, conversational AI, light transport simulation (e.g., ray-tracing, path tracing, etc.), collaborative content creation for 3D assets, cloud computing and/or any other suitable applications.

Disclosed embodiments may be incorporated or integrated in a variety of different systems such as automotive systems (e.g., a human-machine interface for an autonomous or semi-autonomous machine), systems implemented using a robot, aerial systems, medial systems, boating systems, smart area monitoring systems, systems for performing deep learning operations, systems for performing simulation and digital twin operations, systems implemented using an edge device, systems incorporating one or more virtual machines (VMs), systems for performing synthetic data generation operations, systems implemented at least partially in a data center, systems for performing conversational AI operations, systems for performing light transport simulation, systems for performing collaborative content creation for 3D assets, systems implemented at least partially using cloud computing resources, and/or other types of systems.

In at least one embodiment, computer system 800 may include, without limitation, processor 802 that may include, without limitation, one or more execution units 808 to perform machine learning model training and/or inferencing according to techniques described herein. In at least one embodiment, computer system 800 is a single processor desktop or server system, but in another embodiment computer system 800 may be a multiprocessor system. In at least one embodiment, processor 802 may include, without limitation, a complex instruction set computer (“CISC”) microprocessor, a reduced instruction set computing (“RISC”) microprocessor, a very long instruction word (“VLIW”) microprocessor, a processor implementing a combination of instruction sets, or any other processor device, such as a digital signal processor, for example. In at least one embodiment, processor 802 may be coupled to a processor bus 810 that may transmit data signals between processor 802 and other components in computer system 800.

In at least one embodiment, processor 802 may include, without limitation, a Level 1 (“L1”) internal cache memory (“cache”) 804. In at least one embodiment, processor 802 may have a single internal cache or multiple levels of internal cache. In at least one embodiment, cache memory may reside external to processor 802. Other embodiments may also include a combination of both internal and external caches depending on particular implementation and needs. In at least one embodiment, register file 806 may store different types of data in various registers including, without limitation, integer registers, floating point registers, status registers, and instruction pointer register.

In at least one embodiment, execution unit 808, including, without limitation, logic to perform integer and floating point operations, also resides in processor 802. In at least one embodiment, processor 802 may also include a microcode (“ucode”) read only memory (“ROM”) that stores microcode for certain macro instructions. In at least one embodiment, execution unit 808 may include logic to handle a packed instruction set 809. In at least one embodiment, by including packed instruction set 809 in an instruction set of a general-purpose processor 802, along with associated circuitry to execute instructions, operations used by many multimedia applications may be performed using packed data in a general-purpose processor 802. In one or more embodiments, many multimedia applications may be accelerated and executed more efficiently by using full width of a processor's data bus for performing operations on packed data, which may eliminate need to transfer smaller units of data across processor's data bus to perform one or more operations one data element at a time.

In at least one embodiment, execution unit 808 may also be used in microcontrollers, embedded processors, graphics devices, DSPs, and other types of logic circuits. In at least one embodiment, computer system 800 may include, without limitation, a memory 820. In at least one embodiment, memory 820 may be implemented as a Dynamic Random Access Memory (“DRAM”) device, a Static Random Access Memory (“SRAM”) device, flash memory device, or other memory device. In at least one embodiment, memory 820 may store instruction(s) 819 and/or data 821 represented by data signals that may be executed by processor 802.

In at least one embodiment, system logic chip may be coupled to processor bus 810 and memory 820. In at least one embodiment, system logic chip may include, without limitation, a memory controller hub (“MCH”) 816, and processor 802 may communicate with MCH 816 via processor bus 810. In at least one embodiment, MCH 816 may provide a high bandwidth memory path 818 to memory 820 for instruction and data storage and for storage of graphics commands, data and textures. In at least one embodiment, MCH 816 may direct data signals between processor 802, memory 820, and other components in computer system 800 and to bridge data signals between processor bus 810, memory 820, and a system I/O 822. In at least one embodiment, system logic chip may provide a graphics port for coupling to a graphics controller. In at least one embodiment, MCH 816 may be coupled to memory 820 through a high bandwidth memory path 818 and graphics/video card 812 may be coupled to MCH 816 through an Accelerated Graphics Port (“AGP”) interconnect 814.

In at least one embodiment, computer system 800 may use system I/O 822 that is a proprietary hub interface bus to couple MCH 816 to I/O controller hub (“ICH”) 830. In at least one embodiment, ICH 830 may provide direct connections to some I/O devices via a local I/O bus. In at least one embodiment, local I/O bus may include, without limitation, a high-speed I/O bus for connecting peripherals to memory 820, chipset, and processor 802. Examples may include, without limitation, an audio controller 829, a firmware hub (“flash BIOS”) 828, a wireless transceiver 826, a data storage 824, a legacy I/O controller 823 containing user input and keyboard interfaces 825, a serial expansion port 827, such as Universal Serial Bus (“USB”), and a network controller 834. Data storage 824 may comprise a hard disk drive, a floppy disk drive, a CD-ROM device, a flash memory device, or other mass storage device.

In at least one embodiment, FIG. 8 illustrates a system, which includes interconnected hardware devices or “chips”, whereas in other embodiments, FIG. 8 may illustrate an exemplary System on a Chip (“SoC”). In at least one embodiment, devices may be interconnected with proprietary interconnects, standardized interconnects (e.g., PCIe) or some combination thereof. In at least one embodiment, one or more components of computer system 800 are interconnected using compute express link (CXL) interconnects.

Such components can be used for interaction environments.

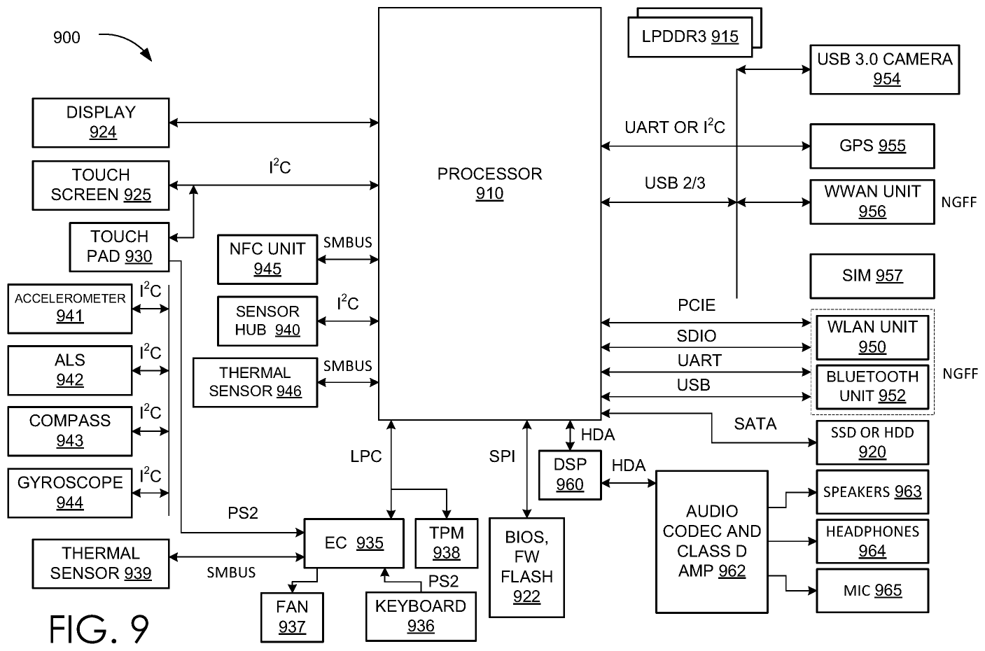

FIG. 9 is a block diagram illustrating an electronic device 900 for utilizing a processor 910, according to at least one embodiment. In at least one embodiment, electronic device 900 may be, for example and without limitation, a notebook, a tower server, a rack server, a blade server, a laptop, a desktop, a tablet, a mobile device, a phone, an embedded computer, or any other suitable electronic device.

In at least one embodiment, system 900 may include, without limitation, processor 910 communicatively coupled to any suitable number or kind of components, peripherals, modules, or devices. In at least one embodiment, processor 910 coupled using a bus or interface, such as a 1° C. bus, a System Management Bus (“SMBus”), a Low Pin Count (LPC) bus, a Serial Peripheral Interface (“SPI”), a High Definition Audio (“HDA”) bus, a Serial Advance Technology Attachment (“SATA”) bus, a Universal Serial Bus (“USB”) (versions 1, 2, 3), or a Universal Asynchronous Receiver/Transmitter (“UART”) bus. In at least one embodiment, FIG. 9 illustrates a system, which includes interconnected hardware devices or “chips”, whereas in other embodiments, FIG. 9 may illustrate an exemplary System on a Chip (“SoC”). In at least one embodiment, devices illustrated in FIG. 9 may be interconnected with proprietary interconnects, standardized interconnects (e.g., PCIe) or some combination thereof. In at least one embodiment, one or more components of FIG. 9 are interconnected using compute express link (CXL) interconnects.

In at least one embodiment, FIG. 9 may include a display 924, a touch screen 925, a touch pad 930, a Near Field Communications unit (“NFC”) 945, a sensor hub 940, a thermal sensor 946, an Express Chipset (“EC”) 935, a Trusted Platform Module (“TPM”) 938, BIOS/firmware/flash memory (“BIOS, FW Flash”) 922, a DSP 960, a drive 920 such as a Solid State Disk (“SSD”) or a Hard Disk Drive (“HDD”), a wireless local area network unit (“WLAN”) 950, a Bluetooth unit 952, a Wireless Wide Area Network unit (“WWAN”) 956, a Global Positioning System (GPS) 955, a camera (“USB 3.0 camera”) 954 such as a USB 3.0 camera, and/or a Low Power Double Data Rate (“LPDDR”) memory unit (“LPDDR3”) 915 implemented in, for example, LPDDR3 standard. These components may each be implemented in any suitable manner.

In at least one embodiment, other components may be communicatively coupled to processor 910 through components discussed above. In at least one embodiment, an accelerometer 941, Ambient Light Sensor (“ALS”) 942, compass 943, and a gyroscope 944 may be communicatively coupled to sensor hub 940. In at least one embodiment, thermal sensor 939, a fan 937, a keyboard 946, and a touch pad 930 may be communicatively coupled to EC 935. In at least one embodiment, speaker 963, headphones 964, and microphone (“mic”) 965 may be communicatively coupled to an audio unit (“audio codec and class d amp”) 962, which may in turn be communicatively coupled to DSP 960. In at least one embodiment, audio unit 964 may include, for example and without limitation, an audio coder/decoder (“codec”) and a class D amplifier. In at least one embodiment, SIM card (“SIM”) 957 may be communicatively coupled to WWAN unit 956. In at least one embodiment, components such as WLAN unit 950 and Bluetooth unit 952, as well as WWAN unit 956 may be implemented in a Next Generation Form Factor (“NGFF”).

Such components can be used for interaction environments.

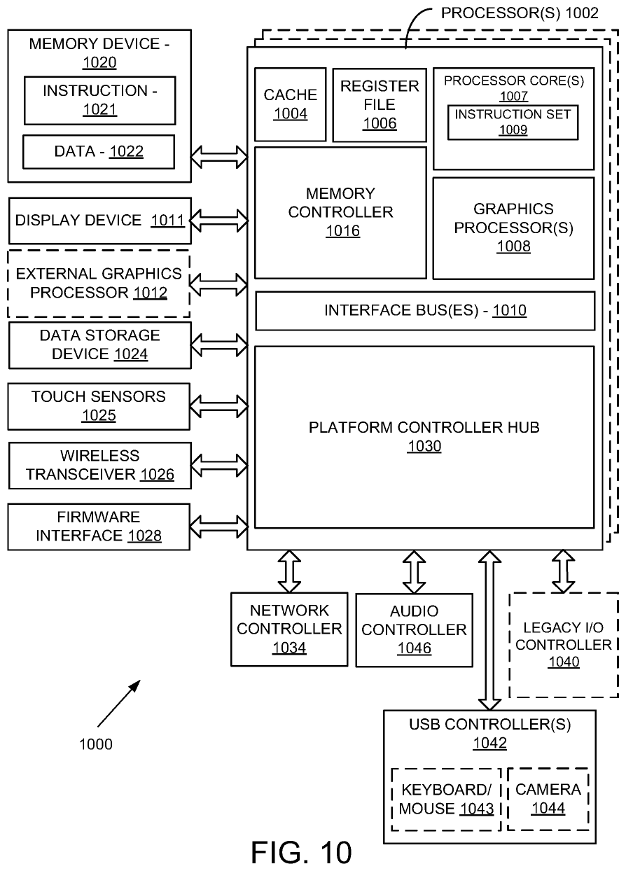

FIG. 10 is a block diagram of a processing system, according to at least one embodiment. In at least one embodiment, system 1000 includes one or more processors 1002 and one or more graphics processors 1008, and may be a single processor desktop system, a multiprocessor workstation system, or a server system or datacenter having a large number of collectively or separably managed processors 1002 or processor cores 1007. In at least one embodiment, system 1000 is a processing platform incorporated within a system-on-a-chip (SoC) integrated circuit for use in mobile, handheld, or embedded devices.

In at least one embodiment, system 1000 can include, or be incorporated within a server-based gaming platform, a cloud computing host platform, a virtualized computing platform, a game console, including a game and media console, a mobile gaming console, a handheld game console, or an online game console. In at least one embodiment, system 1000 is a mobile phone, smart phone, tablet computing device or mobile Internet device. In at least one embodiment, processing system 1000 can also include, couple with, or be integrated within a wearable device, such as a smart watch wearable device, smart eyewear device, augmented reality device, edge device, Internet of Things (“IoT”) device, or virtual reality device. In at least one embodiment, processing system 1000 is a television or set top box device having one or more processors 1002 and a graphical interface generated by one or more graphics processors 1008.

In at least one embodiment, one or more processors 1002 each include one or more processor cores 1007 to process instructions which, when executed, perform operations for system and user software. In at least one embodiment, each of one or more processor cores 1007 is configured to process a specific instruction set 1009. In at least one embodiment, instruction set 1009 may facilitate Complex Instruction Set Computing (CISC), Reduced Instruction Set Computing (RISC), or computing via a Very Long Instruction Word (VLIW). In at least one embodiment, processor cores 1007 may each process a different instruction set 1009, which may include instructions to facilitate emulation of other instruction sets. In at least one embodiment, processor core 1007 may also include other processing devices, such a Digital Signal Processor (DSP).

In at least one embodiment, processor 1002 includes cache memory 1004. In at least one embodiment, processor 1002 can have a single internal cache or multiple levels of internal cache. In at least one embodiment, cache memory is shared among various components of processor 1002. In at least one embodiment, processor 1002 also uses an external cache (e.g., a Level-3 (L3) cache or Last Level Cache (LLC)) (not shown), which may be shared among processor cores 1007 using known cache coherency techniques. In at least one embodiment, register file 1006 is additionally included in processor 1002 which may include different types of registers for storing different types of data (e.g., integer registers, floating point registers, status registers, and an instruction pointer register). In at least one embodiment, register file 1006 may include general-purpose registers or other registers.

In at least one embodiment, one or more processor(s) 1002 are coupled with one or more interface bus(es) 1010 to transmit communication signals such as address, data, or control signals between processor 1002 and other components in system 1000. In at least one embodiment, interface bus 1010, in one embodiment, can be a processor bus, such as a version of a Direct Media Interface (DMI) bus. In at least one embodiment, interface 1010 is not limited to a DMI bus, and may include one or more Peripheral Component Interconnect buses (e.g., PCI, PCI Express), memory busses, or other types of interface busses. In at least one embodiment processor(s) 1002 include an integrated memory controller 1016 and a platform controller hub 1030. In at least one embodiment, memory controller 1016 facilitates communication between a memory device and other components of system 1000, while platform controller hub (PCH) 1030 provides connections to I/O devices via a local I/O bus.

In at least one embodiment, memory device 1020 can be a dynamic random access memory (DRAM) device, a static random access memory (SRAM) device, flash memory device, phase-change memory device, or some other memory device having suitable performance to serve as process memory. In at least one embodiment memory device 1020 can operate as system memory for system 1000, to store data 1022 and instructions 1021 for use when one or more processors 1002 executes an application or process. In at least one embodiment, memory controller 1016 also couples with an optional external graphics processor 1012, which may communicate with one or more graphics processors 1008 in processors 1002 to perform graphics and media operations. In at least one embodiment, a display device 1011 can connect to processor(s) 1002. In at least one embodiment display device 1011 can include one or more of an internal display device, as in a mobile electronic device or a laptop device or an external display device attached via a display interface (e.g., DisplayPort, etc.). In at least one embodiment, display device 1011 can include a head mounted display (HMD) such as a stereoscopic display device for use in virtual reality (VR) applications or augmented reality (AR) applications.

In at least one embodiment, platform controller hub 1030 enables peripherals to connect to memory device 1020 and processor 1002 via a high-speed I/O bus. In at least one embodiment, I/O peripherals include, but are not limited to, an audio controller 1046, a network controller 1034, a firmware interface 1028, a wireless transceiver 1026, touch sensors 1025, a data storage device 1024 (e.g., hard disk drive, flash memory, etc.). In at least one embodiment, data storage device 1024 can connect via a storage interface (e.g., SATA) or via a peripheral bus, such as a Peripheral Component Interconnect bus (e.g., PCI, PCI Express). In at least one embodiment, touch sensors 1025 can include touch screen sensors, pressure sensors, or fingerprint sensors. In at least one embodiment, wireless transceiver 1026 can be a Wi-Fi transceiver, a Bluetooth transceiver, or a mobile network transceiver such as a 3G, 4G, or Long Term Evolution (LTE) transceiver. In at least one embodiment, firmware interface 1028 enables communication with system firmware, and can be, for example, a unified extensible firmware interface (UEFI). In at least one embodiment, network controller 1034 can enable a network connection to a wired network. In at least one embodiment, a high-performance network controller (not shown) couples with interface bus 1010. In at least one embodiment, audio controller 1046 is a multi-channel high definition audio controller. In at least one embodiment, system 1000 includes an optional legacy I/O controller 1040 for coupling legacy (e.g., Personal System 2 (PS/2)) devices to system. In at least one embodiment, platform controller hub 1030 can also connect to one or more Universal Serial Bus (USB) controllers 1042 connect input devices, such as keyboard and mouse 1043 combinations, a camera 1044, or other USB input devices.

In at least one embodiment, an instance of memory controller 1016 and platform controller hub 1030 may be integrated into a discreet external graphics processor, such as external graphics processor 1012. In at least one embodiment, platform controller hub 1030 and/or memory controller 1016 may be external to one or more processor(s) 1002. For example, in at least one embodiment, system 1000 can include an external memory controller 1016 and platform controller hub 1030, which may be configured as a memory controller hub and peripheral controller hub within a system chipset that is in communication with processor(s) 1002.

Such components can be used for interaction environments.

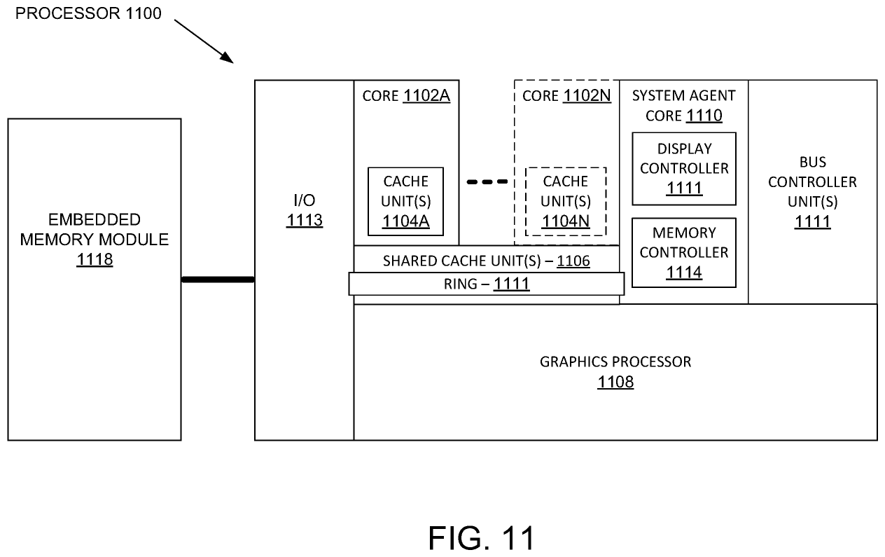

FIG. 11 is a block diagram of a processor 1100 having one or more processor cores 1102A-1102N, an integrated memory controller 1114, and an integrated graphics processor 1108, according to at least one embodiment. In at least one embodiment, processor 1100 can include additional cores up to and including additional core 1102N represented by dashed lined boxes. In at least one embodiment, each of processor cores 1102A-1102N includes one or more internal cache units 1104A-1104N. In at least one embodiment, each processor core also has access to one or more shared cached units 1106.

In at least one embodiment, internal cache units 1104A-1104N and shared cache units 1106 represent a cache memory hierarchy within processor 1100. In at least one embodiment, cache memory units 1104A-1104N may include at least one level of instruction and data cache within each processor core and one or more levels of shared mid-level cache, such as a Level 2 (L2), Level 3 (L3), Level 4 (L4), or other levels of cache, where a highest level of cache before external memory is classified as an LLC. In at least one embodiment, cache coherency logic maintains coherency between various cache units 1106 and 1104A-1104N.

In at least one embodiment, processor 1100 may also include a set of one or more bus controller units 1116 and a system agent core 1110. In at least one embodiment, one or more bus controller units 1116 manage a set of peripheral buses, such as one or more PCI or PCI express busses. In at least one embodiment, system agent core 1110 provides management functionality for various processor components. In at least one embodiment, system agent core 1110 includes one or more integrated memory controllers 1114 to manage access to various external memory devices (not shown).

In at least one embodiment, one or more of processor cores 1102A-1102N include support for simultaneous multi-threading. In at least one embodiment, system agent core 1110 includes components for coordinating and operating cores 1102A-1102N during multi-threaded processing. In at least one embodiment, system agent core 1110 may additionally include a power control unit (PCU), which includes logic and components to regulate one or more power states of processor cores 1102A-1102N and graphics processor 1108.

In at least one embodiment, processor 1100 additionally includes graphics processor 1108 to execute graphics processing operations. In at least one embodiment, graphics processor 1108 couples with shared cache units 1106, and system agent core 1110, including one or more integrated memory controllers 1114. In at least one embodiment, system agent core 1110 also includes a display controller 1111 to drive graphics processor output to one or more coupled displays. In at least one embodiment, display controller 1111 may also be a separate module coupled with graphics processor 1108 via at least one interconnect, or may be integrated within graphics processor 1108.

In at least one embodiment, a ring based interconnect unit 1112 is used to couple internal components of processor 1100. In at least one embodiment, an alternative interconnect unit may be used, such as a point-to-point interconnect, a switched interconnect, or other techniques. In at least one embodiment, graphics processor 1108 couples with ring interconnect 1112 via an I/O link 1113.

In at least one embodiment, I/O link 1113 represents at least one of multiple varieties of I/O interconnects, including an on package I/O interconnect which facilitates communication between various processor components and a high-performance embedded memory module 1118, such as an eDRAM module. In at least one embodiment, each of processor cores 1102A-1102N and graphics processor 1108 use embedded memory modules 1118 as a shared Last Level Cache.

In at least one embodiment, processor cores 1102A-1102N are homogenous cores executing a common instruction set architecture. In at least one embodiment, processor cores 1102A-1102N are heterogeneous in terms of instruction set architecture (ISA), where one or more of processor cores 1102A-1102N execute a common instruction set, while one or more other cores of processor cores 1102A-1102N executes a subset of a common instruction set or a different instruction set. In at least one embodiment, processor cores 1102A-1102N are heterogeneous in terms of microarchitecture, where one or more cores having a relatively higher power consumption couple with one or more power cores having a lower power consumption. In at least one embodiment, processor 1100 can be implemented on one or more chips or as an SoC integrated circuit.

Such components can be used for establishing interaction environments.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. Term “connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. Use of term “set” (e.g., “a set of items”) or “subset,” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B, and at least one of C each to be present. In addition, unless otherwise noted or contradicted by context, term “plurality” indicates a state of being plural (e.g., “a plurality of items” indicates multiple items). A plurality is at least two items, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. A set of non-transitory computer-readable storage media, in at least one embodiment, comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) and/or a data processing unit (“DPU”) executes other instructions. In at least one embodiment, different components of a computer system have separate processors and different processors execute different subsets of instructions.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

All references, including publications, patent applications, and patents, cited herein are hereby incorporated by reference to same extent as if each reference were individually and specifically indicated to be incorporated by reference and were set forth in its entirety herein.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be any processor capable of general purpose processing such as a CPU, GPU, or DPU. As non-limiting examples, “processor” may be any microcontroller or dedicated processing unit such as a DSP, image signal processor (“ISP”), arithmetic logic unit (“ALU”), vision processing unit (“VPU”), tree traversal unit (“TTU”), ray tracing core, tensor tracing core, tensor processing unit (“TPU”), embedded control unit (“ECU”), and the like. As non-limiting examples, “processor” may be a hardware accelerator, such as a PVA (programmable vision accelerator), DLA (deep learning accelerator), etc. As non-limiting examples, “processor” may also include one or more virtual instances of a CPU, GPU, etc., hosted on an underlying hardware component executing one or more virtual machines. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. Terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. Obtaining, acquiring, receiving, or inputting analog and digital data can be accomplished in a variety of ways such as by receiving data as a parameter of a function call or a call to an application programming interface. In some implementations, process of obtaining, acquiring, receiving, or inputting analog or digital data can be accomplished by transferring data via a serial or parallel interface. In another implementation, process of obtaining, acquiring, receiving, or inputting analog or digital data can be accomplished by transferring data via a computer network from providing entity to acquiring entity. References may also be made to providing, outputting, transmitting, sending, or presenting analog or digital data. In various examples, process of providing, outputting, transmitting, sending, or presenting analog or digital data can be accomplished by transferring data as an input or output parameter of a function call, a parameter of an application programming interface or interprocess communication mechanism.

Although discussion above sets forth example implementations of described techniques, other architectures may be used to implement described functionality, and are intended to be within scope of this disclosure. Furthermore, although specific distributions of responsibilities are defined above for purposes of discussion, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A computer-implemented method, comprising:
receiving a first image file associated with a first native source format;
receiving a second image file associated with a second native source format;
rendering a combined visualization of the first image file and the second image file within an interaction environment;
detecting, within the combined visualization, one or more individual components forming the combined visualization;
performing, based at least in part on a set of evaluation procedures, an automated assembly evaluation on the one or more individual components; and
providing, for a selected individual component, an evaluation result.

2. The computer-implemented method of claim 1, wherein the automated assembly evaluation is a volumetric difference check.

3. The computer-implemented method of claim 1, wherein the automated assembly evaluation is an interference check.

4. The computer-implemented method of claim 1, wherein the first native source format is a mechanical computer aided drafting (CAD) software file and the second native source format is an electrical CAD software file.

5. The computer-implemented method of claim 3, further comprising:
retrieving a bill of materials for the first image file; and
identifying, within the combined visualization, one or more individual components based, at least in part, on the bill of materials.

6. The computer-implemented method of claim 1, further comprising:
determining a first individual component according to the first image file;
determining a second individual component according to the second image file;
determining a version difference between the first individual component and the second individual component; and
providing an alert.

7. The computer-implemented method of claim 1, further comprising:
receiving credentials from a user;
determining, based at least in part on preferences for the user, one or more evaluation types associated with the user; and
presenting, within the interaction environment, a list of evaluation results corresponding to the one or more evaluation types.

8. A system, comprising:
at least one processor; and
memory including instructions that, when executed by the at least one processor, cause the system to:
render a combined virtualization of a plurality of input files;
provide an interface for interaction with the combined virtualization;
receive a selection of a component of the combined virtualization; and
provide build information for the component.

9. The system of claim 8, wherein the plurality of input files correspond to different native software sources.

10. The system of claim 3, wherein the system is comprised in at least one of:
a human-machine interface system of an autonomous or semi-autonomous machine;
a human-machine interface system of a gaming machine;
a system for performing conversational AI operations;
a system for performing simulation operations;
a system for performing digital twin operations;
a system for performing deep learning operations;
a system for performing video playback;
a system for performing rendering operations;
a system implemented using an edge device;
a system implemented using a robot;
a system incorporating one or more virtual machines (VMs);
a system implemented at least partially in a data center; or
a system implemented at least partially using cloud computing resources.

11. The system of claim 8, wherein the instructions, when executed by the at least one processor, further cause the system to:
identify a conflict between at least two input files of the plurality of input files;
provide a notification associated with the conflict.

12. The system of claim 11, wherein the conflict is at least one of an interference, a version divergence, or a rule violation.

13. The system of claim 11, wherein the instructions, when executed by the at least one processor, further cause the system to:
retrieve a set of rules associated with the conflict.

14. The system of claim 8, wherein the instructions, when executed by the at least one processor, further cause the system to:
retrieve metadata for the component, wherein the build information is associated, at least in part, with the metadata.

15. The system of claim 8, wherein the instructions, when executed by the at least one processor, further cause the system to:
execute an automated assembly evaluation on the combined virtualization.

16. A method, comprising:
receiving a plurality of design files, from a plurality of different native formats;
generating, from the plurality of design files, a common design build;
rendering the common design build within an interaction environment; and
performing one or more diagnostic evaluations of the common design build.

17. The method of claim 16, further comprising:
receiving a selection of a component forming the common design build;
identifying the component based on one or more of a feature evaluation of the component or a build list;
determining a version of the component; and
providing, as an overlay, a visualization of the component in accordance with the version.

18. The method of claim 16, further comprising:
determining the version of the component based on a first design file of the plurality of design files;
determining a second version of the component based on a second design file of the plurality of design files;
identifying one or more differences between the version and the second version; and
performing the one or more diagnostic evaluations on the common design build using both the version and the second version.

19. The method of claim 18, further comprising:
recommending one of the version or the second version based, at least in part, on the one or more diagnostic evaluations.

20. The method of claim 19, wherein the a first native format is a mechanical computer aided drafting (CAD) software file and a second native format is an electrical CAD software file.
